(19) United States
(12) Patent Application Publication
(10) Pub. No.: US 2026/0039095 A1
(43) Pub. Date: Feb. 5, 2026

(54) DIRECT CURRENT POWER DISTRIBUTION CIRCUIT CONTROL

(71) Applicant: Amphenol Network Solutions, Inc., Liberty Lake, WA (US)

(72) Inventors: Jonathan White, Liberty Lake, WA (US); Lucas James Hutyler, Spokane Valley, WA (US); Timothy Meyer, Liberty Lake, WA (US); Greg Hilbert, Liberty Lake, WA (US); April Badders, Liberty Lake, WA (US); Jason Charette, Liberty Lake, WA (US)

(21) Appl. No.: 19/285,744

(22) Filed: Jul. 30, 2025

Related U.S. Application Data
(60) Provisional application No. 63/677,910, filed on Jul. 31, 2024.

(51) Int. Cl. H02B 1/20; H02B 1/04; H02B 1/24; H05K 7/14

(52) U.S. Cl. CPC H02B 1/20; H02B 1/04; H02B 1/24; H05K 7/1492

(57) ABSTRACT

A power distribution panel may include a power input configured to receive direct-current power from a source. The power distribution panel may include a bus bar electrically coupled to the power input. The power distribution panel may include a plurality of outputs electrically coupled to the bus bar, each of the plurality of outputs coupled to the bus bar through a respective switch device such as a field effect transistor and overcurrent device coupled in series with the switch device, wherein the switch device is controllable by a controller of the power distribution panel.

### CROSS-REFERENCE TO RELATED APPLICATIONS

This application claims priority to Provisional U.S. Application No. 63/677,910, titled “DIRECT-CURRENT DISTRIBUTION CIRCUIT CONTROL”, filed Jul. 31, 2024, which is hereby incorporated by reference in its entirety.

### TECHNOLOGY FIELD

The present disclosure relates to power distribution systems, and more particularly to a direct-current power distribution panel with remote power cycling capabilities for data center and telecommunications equipment.

### BACKGROUND

Industry-wide, the design of power distribution systems is essentially non-standardized. As such, secondary power distribution system components, made by data communication manufacturers, are customized for each application. In view of the non-standardization, each secondary power distribution system requires a unique manufacturing line to build, increasing cost. Specifically, each of the non-standardized secondary power distribution systems may require a specific chassis, specific components, and specific tools to manufacture. This increases the cost of manufacturing the secondary power distribution systems. Accordingly, there remains a desire to standardize power distribution equipment to not require a specific chassis, specific components, or specific tools to manufacture, and thus reduce cost.

Power distribution systems in data centers and telecommunications facilities face significant challenges in efficiently managing and controlling direct-current power delivery to various equipment. The increasing complexity and scale of modern data centers require more flexible and scalable power distribution solutions that can adapt to changing power needs and equipment configurations. Existing power distribution systems often lack granular control and monitoring capabilities at the individual circuit level. This limitation makes it difficult to remotely manage power cycling, monitor power consumption, and quickly diagnose issues for specific pieces of equipment. Additionally, current systems typically rely on manual intervention for tasks like power cycling or adjusting circuit breaker settings, which can be time-consuming and error-prone in large-scale environments. For example, when troubleshooting network equipment in a data center, technicians may need to physically access the power distribution panel to cycle power to a specific device. This process can be inefficient, especially in facilities with restricted access or remote locations. Furthermore, existing solutions often provide limited data on power usage and circuit status, making it challenging to optimize energy consumption or proactively identify potential overload conditions before they cause disruptions.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

The power distribution panel includes a power input configured to receive direct-current power from a source, a bus bar electrically coupled to the power input, and a plurality of outputs electrically coupled to the bus bar. Each of the plurality of outputs is coupled to the bus bar through a respective switch device such as a field effect transistor and overcurrent device coupled in series with the field effect transistor. The field effect transistor is controllable by a controller of the power distribution panel. The power distribution panel may include a controller configured to remotely control power delivery to each of the plurality of outputs by controlling the respective field effect transistors. The controller may be further configured to schedule power cycling sequences for the plurality of outputs. The overcurrent device may comprise at least one of a circuit breaker or a fuse. The power distribution panel may include a monitoring system configured to monitor power consumption of each of the plurality of outputs. The monitoring system may be configured to provide real-time data on current, voltage, and temperature for each of the plurality of outputs. The monitoring system may be further configured to generate alerts based on predefined threshold values for current, voltage, and temperature.

The system for distributing direct-current power includes a server rack and a power distribution panel mounted in the server rack. The power distribution panel comprises a power input for receiving direct-current power, a bus bar coupled to the power input, and a plurality of output circuits. Each output circuit comprises a field effect transistor coupled to the bus bar, an overcurrent protection device coupled in series with the field effect transistor, and an output connection for providing power to a component in the server rack. The system may include a controller configured to remotely control power delivery to each of the plurality of output circuits by controlling the respective field effect transistors. The controller may be further configured to schedule power cycling sequences for the plurality of output circuits. Scheduling power cycling sequences may comprise coordinating power delivery timing to avoid simultaneous activation of multiple output circuits. The system may include a monitoring system configured to monitor power consumption of each of the plurality of output circuits and provide real-time data on current, voltage, and temperature. The monitoring system may be further configured to generate alerts based on predefined threshold values for current, voltage, and temperature.

The method of distributing power using a power distribution panel includes receiving direct-current power at a power input of the power distribution panel, distributing the direct-current power from the power input to a bus bar, and selectively providing power from the bus bar to a plurality of outputs. Providing power to each output comprises controlling a field effect transistor coupled between the bus bar and the output, and protecting the output with an overcurrent device coupled in series with the field effect transistor. The method may include monitoring power consumption of each of the plurality of outputs. Monitoring power consumption may comprise measuring current, voltage, and temperature for each of the plurality of outputs. The method may include generating alerts based on predefined threshold values for current, voltage, and temperature. The method may include remotely controlling power delivery to each of the plurality of outputs by controlling the respective field effect transistors. The method may include scheduling power cycling sequences for the plurality of outputs. Scheduling power cycling sequences may comprise coordinating power delivery timing to avoid simultaneous activation of multiple outputs.

The foregoing general description of the illustrative embodiments and the following detailed description thereof are merely exemplary aspects of the teachings of this disclosure and are not restrictive.

### BRIEF DESCRIPTION OF FIGURES

Non-limiting and non-exhaustive examples are described with reference to the following figures.

FIG. 1 illustrates an example direct-current power distribution system, showing power flow from a source to components in a server rack, in accordance with examples described herein.

FIG. 2 depicts an example distribution circuit within a power distribution panel, demonstrating power routing through protective and control elements, according to aspects of the present description.

FIG. 3 shows an example block diagram of a power distribution and monitoring system for a server rack, illustrating centralized control and monitoring capabilities, in accordance with examples of the description.

FIG. 4 presents an example block diagram of a power distribution system controller, highlighting various monitoring and control modules for comprehensive system management, according to aspects of the present description.

FIG. 5 illustrates an example monitoring interface for a power distribution system, showing a user interface for viewing panel information and monitoring parameters, in accordance with examples of the present description.

FIG. 6 depicts an example internal view of a power distribution unit, revealing an example component arrangement within a single rack unit housing, according to aspects of the present description.

FIG. 7 shows another example internal view of the power distribution unit of FIG. 6, highlighting power routing and control components, in accordance with examples of the description.

FIG. 8 presents an example flowchart for a method of distributing power using a power distribution panel, according to aspects of the present disclosure.

### DETAILED DESCRIPTION

The following description sets forth exemplary aspects of the present disclosure. It should be recognized, however, that such description is not intended as a limitation on the scope of the present disclosure. Rather, the description also encompasses combinations and modifications to those exemplary aspects described herein.

As discussed above, existing power distribution systems in data centers and telecommunications facilities often lack granular control and monitoring capabilities at the individual circuit level, making it difficult to remotely manage power cycling, monitor power consumption, and quickly diagnose issues for specific pieces of equipment. Additionally, current systems typically rely on manual intervention for tasks like power cycling or adjusting circuit breaker settings, which can be time-consuming and error-prone in large-scale environments.

This application relates to a power distribution panel for distributing direct-current power to multiple components in data centers and telecommunications facilities. The power distribution panel includes a power input, a bus bar, and multiple outputs, each coupled to the bus bar through a switch device such as a field effect transistor and an overcurrent device in series. Though examples may be described herein with reference to a field effect transistor for a switch device, the switch device may also include components such as relays, bipolar junction transistors (BJTs), insulated gate bipolar transistors (IGBTs), solid state relays (SSRs), or other such switching devices. A controller enables remote power cycling and monitoring of individual circuits, allowing for granular control, scheduled power sequences, and real-time monitoring of current, voltage, and temperature. This system addresses the limitations of existing power distribution systems by providing remote management capabilities, reducing the need for manual intervention, and enabling more efficient power management and troubleshooting in large-scale environments.

The present disclosure relates to power distribution systems for data centers and telecommunications facilities, specifically focusing on direct-current power distribution panels with advanced control and monitoring capabilities. This field encompasses the design and implementation of electrical systems that efficiently and reliably deliver power to critical equipment in large-scale computing and communication environments.

Existing power distribution systems in data centers and telecommunications facilities often lack granular control and monitoring capabilities at the individual circuit level. This limitation makes it challenging to remotely manage power cycling, monitor power consumption, and quickly diagnose issues for specific pieces of equipment. Additionally, current systems typically rely on manual intervention for tasks like power cycling or adjusting circuit breaker settings, which can be time-consuming and error-prone in large-scale environments.

The present disclosure introduces a power distribution panel that addresses these challenges by incorporating field effect transistors (FETs) or other switching devices such as relays, bipolar junction transistors (BJTs), insulated gate bipolar transistors (IGBTs), solid state relays (SSRs), or other such switching devices and overcurrent devices in series for each output circuit, coupled with a centralized controller. This innovative design enables remote power cycling and monitoring of individual circuits, allowing for granular control, scheduled power sequences, and real-time monitoring of current, voltage, and temperature. By providing these advanced management capabilities, the disclosure significantly reduces the need for manual intervention and enables more efficient power management and troubleshooting in large-scale environments.

Furthermore, the power distribution panel features a compact, standardized design that can be easily integrated into existing server racks, occupying minimal space while providing high-capacity power distribution. The system's monitoring capabilities extend beyond basic power metrics, offering two-tier alarming and trend analysis functionalities that enable proactive maintenance and optimization of power usage. Additionally, the modular nature of the design allows for scalability and adaptability to various data center and telecommunications facility configurations, providing a versatile solution for diverse power distribution needs.

The power distribution panel described herein offers several technical improvements over existing systems. By incorporating field effect transistors (FETs) or other switching devices such as relays, bipolar junction transistors (BJTs), insulated gate bipolar transistors (IGBTs), solid state relays (SSRs), or other such switching devices and overcurrent devices in series for each output circuit, the panel enables more precise and responsive control of power delivery. This configuration allows for rapid switching and power cycling of individual circuits, reducing the time required for troubleshooting and maintenance operations. The remote control capabilities eliminate the need for physical access to the panel, significantly improving efficiency in large-scale data centers and reducing the risk of human error during manual interventions.

The advanced monitoring system provides real-time data on current, voltage, and temperature for each output, enabling more accurate and timely detection of potential issues. This granular level of monitoring, combined with two-tier alarming and trend analysis functionalities, enhances the overall reliability of the power distribution system by allowing for proactive maintenance and reducing the likelihood of unexpected failures. The ability to analyze power consumption trends also contributes to improved energy efficiency, as it allows data center operators to optimize power usage and identify opportunities for load balancing.

Furthermore, the standardized and compact design of the power distribution panel improves the overall efficiency of a data center infrastructure. By occupying minimal rack space while providing high-capacity power distribution, the panel allows for more efficient use of available space in server racks. This can lead to increased equipment density and improved cooling efficiency in data centers. The modular nature of the design also enhances scalability, allowing data centers to easily adapt their power distribution systems to changing needs without requiring significant infrastructure modifications.

While the power distribution panel described herein is discussed primarily in the context of data centers and telecommunications facilities, the methods, systems, and apparatuses disclosed are not limited to these specific applications. The techniques and configurations presented can be applied to a variety of environments and industries that require efficient and remotely controllable direct-current power distribution. For example, the power distribution panel could be adapted for use in industrial automation systems, transportation infrastructure, renewable energy installations, or large-scale scientific research facilities. The remote control and monitoring capabilities could be particularly valuable in hazardous environments where physical access is limited or dangerous, such as in chemical processing plants or offshore platforms. Additionally, the power management and monitoring techniques described could be applied to mobile or temporary power distribution systems, such as those used in disaster response scenarios or large-scale events. The scalability and modularity of the design allow for adaptation to various power requirements and physical constraints, making the system versatile across different applications and industries.

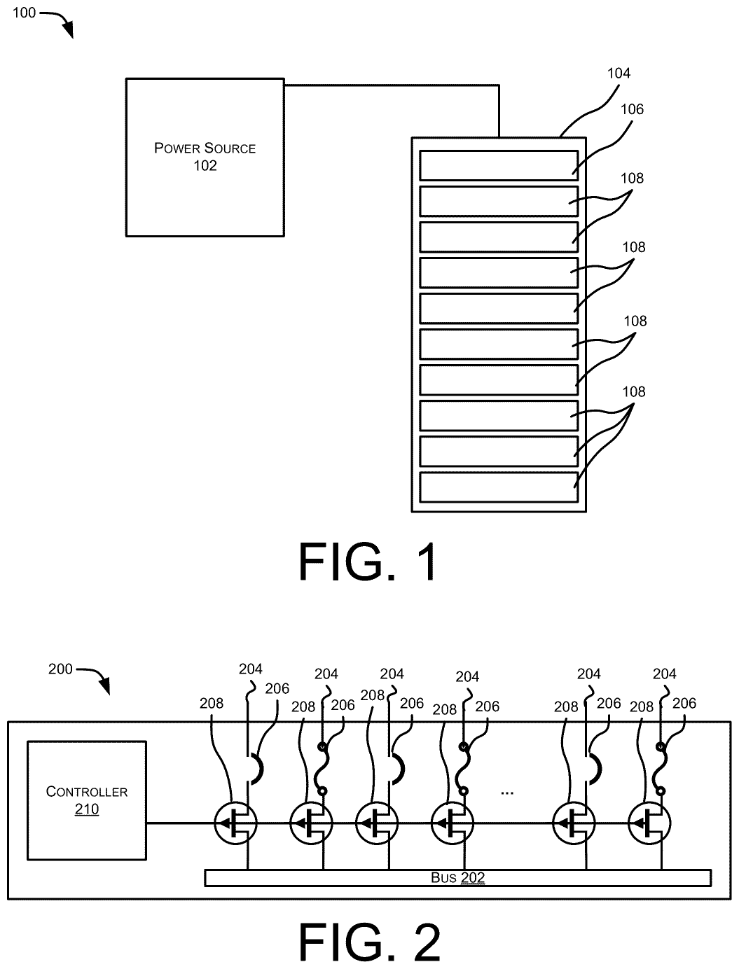

FIG. 1 illustrates a power distribution system 100, in accordance with one embodiment. As an option, the power distribution system 100 may be implemented in the context of any one or more of the embodiments set forth in any previous and/or subsequent Figures and/or description thereof. Of course, however, the power distribution system 100 may be implemented in the context of any desired environment. Further, the aforementioned definitions may equally apply to the description below.

The power distribution system 100 includes a power source 102, a server rack 104, a power distribution panel 106, and system components 108. The power source 102 provides direct-current power to the server rack 104, which houses the power distribution panel 106. The power distribution panel 106 distributes power to multiple system components 108 within the server rack 104.

A power source 102 supplies direct-current power to the power distribution system 100. The power source 102 may be a high-capacity direct-current power supply designed for data center or telecommunications applications. In some cases, the power source 102 may include redundant power supplies to ensure continuous operation in the event of a single supply failure. The power source 102 may be configured to provide a specific voltage level suitable for the system components 108. In various embodiments, the power source 102 may be adjustable to accommodate different voltage requirements of various system components 108. In various embodiments, the power source 102 may incorporate power conditioning features to ensure clean, stable power delivery to the server rack 104. These features may include voltage regulation, noise filtering, and surge protection capabilities.

A server rack 104 houses the components of the power distribution system 100. The server rack 104 may be a standard-sized rack used in data centers and telecommunications facilities. In some cases, the server rack 104 may be designed to accommodate multiple power distribution panels and numerous system components 108. The server rack 104 may include features for efficient cable management and airflow optimization. These features may help maintain proper cooling and organization of the power distribution system 100 components. In various embodiments, the server rack 104 may be equipped with environmental monitoring sensors to track temperature, humidity, and other relevant parameters within the rack enclosure. This data may be used to ensure optimal operating conditions for the power distribution system 100.

A power distribution panel 106 is mounted within the server rack 104 and serves as the central hub for power distribution. The power distribution panel 106 receives direct-current power from the power source 102 and distributes power to multiple system components 108. The power distribution panel 106 occupies one rack unit (1U) of space within the server rack 104, allowing for efficient use of available rack space. Despite the compact size, the power distribution panel 106 may provide power to up to sixteen system components 108 through a single panel.

In various embodiments, the power distribution panel 106 may incorporate advanced thermal management features to ensure efficient operation within the confined space of a 1U form factor. These features may include passive heat sinks, active cooling systems, or thermally optimized component layouts.

System components 108 represent the various devices and equipment powered by the power distribution system 100. These may include servers, network switches, storage devices, and other critical data center or telecommunications equipment. The system components 108 receive power from the power distribution panel 106 through individual output circuits. Each system component 108 may have specific power requirements that are accommodated by the power distribution panel 106.

In various embodiments, the system components 108 may include power management features that allow them to communicate with the power distribution panel 106. This communication may enable advanced power monitoring and control capabilities at the individual component level.

FIG. 2 illustrates a distribution circuit 200 of the power distribution system 100, in accordance with one embodiment. As an option, the distribution circuit 200 may be implemented in the context of any one or more of the embodiments set forth in any previous and/or subsequent Figures and/or description thereof. Of course, however, the distribution circuit 200 may be implemented in the context of any desired environment. Further, the aforementioned definitions may equally apply to the description below.

The distribution circuit 200 includes a power bus 202, output circuits 204, overcurrent devices 206, field effect transistors 208, and a circuit controller 210. These components work together to provide controlled and protected power distribution to the system components 108. The power bus 202 serves as the main power distribution pathway within the power distribution panel 106. The power bus 202 may be a bus bar electrically coupled to the power input from the power source 102. The power bus 202 distributes power to multiple output circuits 204. The power bus 202 may be designed to handle high current loads, with the capacity to provide up to 60 amps per circuit. The material and construction of the power bus 202 may be optimized for efficient power transmission and minimal power loss. In various embodiments, the power bus 202 may incorporate temperature monitoring sensors to detect potential hotspots or overloading conditions. This information may be used by the circuit controller 210 to manage power distribution and prevent thermal issues.

Output circuits 204 branch from the power bus 202 to deliver power to individual system components 108. Each output circuit 204 may be configured to meet the specific power requirements of connected system components 108. The output circuits 204 may include connectors or terminals that allow for easy connection and disconnection of system components 108. This modular approach facilitates maintenance and reconfiguration of the power distribution system 100. In various embodiments, the output circuits 204 may incorporate individual power metering capabilities. This feature allows for precise monitoring of power consumption at the circuit level, enabling advanced energy management and billing functionalities.

Overcurrent devices 206 are connected in series within each output circuit 204. The overcurrent devices 206 may be circuit breakers or fuses designed to protect the system components 108 from excessive current flow. The overcurrent devices 206 may be selected based on the specific current ratings required for each output circuit 204. In some cases, the overcurrent devices 206 may be user-replaceable, allowing for easy maintenance and reconfiguration of the power distribution panel 106. In various embodiments, the overcurrent devices 206 may include electronic trip units that provide advanced protection features such as adjustable trip settings, time-delay functions, and remote monitoring capabilities.

Field effect transistors 208 are positioned in series with the overcurrent devices 206 within each output circuit 204. Though examples may be described herein with reference to a field effect transistor 208 for a switch device, the switch device may also include components such as relays, bipolar junction transistors (BJTs), insulated gate bipolar transistors (IGBTs), solid state relays (SSRs), or other such switching devices. The field effect transistors 208 serve as electronically controllable switches, allowing for remote power cycling and control of individual output circuits 204. The field effect transistors 208 may be selected for their low on-state resistance and high current handling capabilities, ensuring efficient power delivery to the system components 108. The gate terminals of the field effect transistors 208 are connected to the circuit controller 210, enabling precise control of power flow. In various embodiments, the field effect transistors 208 may incorporate built-in current sensing capabilities. This feature allows for real-time current monitoring at the individual circuit level, providing valuable data for power management and fault detection.

A circuit controller 210 manages the operation of the field effect transistors 208 and oversees the overall functionality of the power distribution panel 106. The circuit controller 210 may be a microprocessor-based system with firmware designed for power management and monitoring tasks. The circuit controller 210 may communicate with external management systems, allowing for remote monitoring and control of the power distribution panel 106. This communication may use standard protocols such as SNMP or Modbus, enabling integration with existing data center management platforms. In various embodiments, the circuit controller 210 may incorporate machine learning algorithms to optimize power distribution based on historical usage patterns and real-time data. This advanced functionality may improve energy efficiency and predict potential issues before they occur.

The components of the distribution circuit 200 work together to provide controlled and protected power distribution. The power bus 202 receives power from the power source 102 and distributes power to multiple output circuits 204. Each output circuit 204 includes an overcurrent device 206 and a field effect transistor 208 connected in series. The overcurrent device 206 provides protection against excessive current flow, while the field effect transistor 208 allows for electronic control of power delivery. The circuit controller 210 manages the operation of the field effect transistors 208, enabling remote power cycling and monitoring of individual circuits.

This arrangement allows for granular control and monitoring of power distribution. The circuit controller 210 can selectively enable or disable power to specific output circuits 204 by controlling the corresponding field effect transistors 208. This capability may be useful for scheduled maintenance, energy saving during off-peak hours, or rapid response to fault conditions. The combination of overcurrent devices 206 and field effect transistors 208 provides multiple layers of protection for the system components 108. The overcurrent devices 206 offer traditional circuit protection, while the field effect transistors 208 allow for rapid power cut-off in response to software-detected anomalies or user commands.

The distribution circuit 200 design allows for scalability and flexibility. Additional output circuits 204 can be added to the power bus 202 as needed, up to the maximum capacity of the power distribution panel 106. This modular approach allows the power distribution system 100 to adapt to changing requirements in data center or telecommunications environments. In various embodiments, the power bus 202 may be implemented as a multi-layer bus bar to increase power density within the 1U form factor. This design may allow for higher current capacity or additional output circuits 204 without increasing the overall size of the power distribution panel 106.

In various embodiments, the overcurrent devices 206 may be implemented as electronic circuit breakers rather than traditional mechanical breakers or fuses. Electronic circuit breakers may offer faster response times, more precise trip characteristics, and the ability to be remotely reset by the circuit controller 210. In various embodiments, the field effect transistors 208 may be replaced or supplemented with other solid-state switching devices such as insulated-gate bipolar transistors (IGBTs) or silicon-controlled rectifiers (SCRs). These alternative devices may offer different performance characteristics suitable for specific applications or power levels.

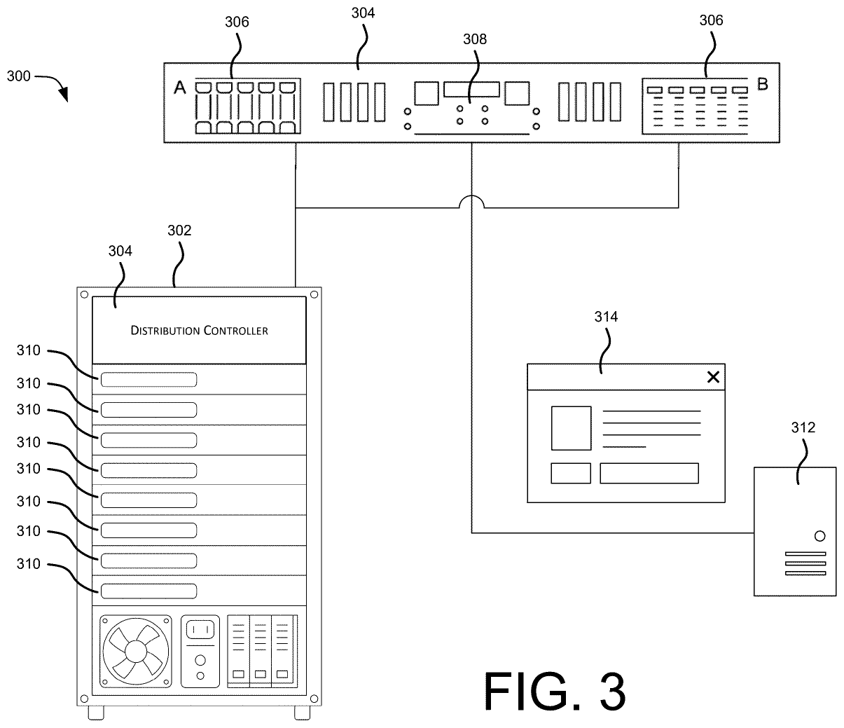

FIG. 3 illustrates a system 300 for distributing power and providing monitoring information for components of a system 300, in accordance with one embodiment. As an option, the system 300 may be implemented in the context of any one or more of the embodiments set forth in any previous and/or subsequent Figures and/or description thereof. Of course, however, the system 300 may be implemented in the context of any desired environment. Further, the aforementioned definitions may equally apply to the description below.

The system 300 includes a server rack 302, a distribution controller 304, power outputs 306, a control interface 308, server components 310, a monitoring system 312, and a monitoring interface 314. These components work together to provide controlled power distribution and monitoring capabilities for a data center or telecommunications facility environment.

The server rack 302 houses the components of the system 300. The server rack 302 may be a standard-sized rack used in data centers and telecommunications facilities. The server rack 302 may be designed to accommodate multiple power distribution panels and numerous server components 310. In some cases, the server rack 302 may include features for efficient cable management and airflow optimization. These features may help maintain proper cooling and organization of the system 300 components. The server rack 302 may be equipped with environmental monitoring sensors to track temperature, humidity, and other relevant parameters within the rack enclosure. This data may be used to ensure optimal operating conditions for the system 300.

A distribution controller 304 manages the power distribution and monitoring functions within the system 300. The distribution controller 304 may be a microprocessor-based system with firmware designed for power management and monitoring tasks. The distribution controller 304 may communicate with external management systems, allowing for remote monitoring and control of the power distribution panel. This communication may use standard protocols such as SNMP or Modbus, enabling integration with existing data center management platforms. The distribution controller 304 may incorporate machine learning algorithms to optimize power distribution based on historical usage patterns and real-time data. This advanced functionality may improve energy efficiency and predict potential issues before they occur.

Power outputs 306 provide the physical connection points for delivering power to the server components 310. The power outputs 306 may be designed to accommodate various connector types commonly used in data center and telecommunications equipment. Each power output 306 may be individually controllable by the distribution controller 304, allowing for granular power management at the component level. This capability enables features such as remote power cycling and scheduled power sequences. The power outputs 306 may incorporate built-in current and voltage sensing capabilities, providing real-time data on power consumption for each connected server component 310.

A control interface 308 provides a means for users or administrators to interact with the system 300. The control interface 308 may be a physical interface located on the power distribution panel or a software interface accessible through a network connection. The control interface 308 may allow users to configure power distribution settings, set up monitoring parameters, and initiate power cycling sequences for individual server components 310 or groups of components. In some cases, the control interface 308 may provide real-time visualizations of power consumption data and system status, enabling quick assessment of the overall health and efficiency of the power distribution system.

Server components 310 represent the various devices and equipment powered by the system 300. These may include servers, network switches, storage devices, and other critical data center or telecommunications equipment. Each server component 310 may have specific power requirements that are accommodated by the power distribution panel through the power outputs 306. The server components 310 receive power from the power distribution panel through individual output circuits. In some cases, the server components 310 may include power management features that allow them to communicate with the distribution controller 304. This communication may enable advanced power monitoring and control capabilities at the individual component level.

A monitoring system 312 tracks and analyzes power usage and system performance within the system 300. The monitoring system 312 may collect data from various sensors and measurement points throughout the power distribution panel and server components 310. The monitoring system 312 may provide real-time data on current, voltage, and power consumption for each power output 306 and server component 310. This granular level of monitoring enables precise tracking of energy usage and identification of potential issues. In some cases, the monitoring system 312 may incorporate predictive analytics capabilities, using historical data and machine learning algorithms to forecast future power needs and potential equipment failures.

A monitoring interface 314 presents the data collected by the monitoring system 312 in a user-friendly format. The monitoring interface 314 may be a graphical user interface accessible through a web browser or dedicated software application. The monitoring interface 314 may display real-time power consumption data, historical trends, and system alerts. Users may be able to customize the interface to focus on specific metrics or components of interest. In some cases, the monitoring interface 314 may provide advanced reporting and analytics tools, allowing users to generate detailed reports on power usage, efficiency metrics, and system performance over time.

The components of the system 300 work together to provide comprehensive power distribution and monitoring capabilities. The distribution controller 304 serves as the central management unit, coordinating power delivery through the power outputs 306 to the server components 310. The control interface 308 allows users to interact with the system 300, configuring settings and initiating actions as needed. The monitoring system 312 continuously collects data on power usage and system performance, which may be displayed through the monitoring interface 314. This real-time monitoring enables quick identification of issues and optimization of power distribution.

The server rack 302 provides the physical infrastructure to house and organize the components of the system 300. By integrating these components within a single rack, the system 300 offers a compact and efficient solution for power distribution and monitoring in data center environments. The distribution controller 304 may be configured to remotely control power delivery to each of the power outputs 306 by controlling the respective field effect transistors within the power distribution panel. This remote control capability enables administrators to manage power to individual server components 310 without physical access to the server rack 302.

The system 300 may be designed to support scheduling of power cycling sequences for the power outputs 306. The distribution controller 304 may coordinate power delivery timing to avoid simultaneous activation of multiple output circuits, which could potentially cause power surges or overloads. By managing power cycling sequences, the system 300 may help optimize power usage during off-peak hours or facilitate scheduled maintenance activities. This functionality may contribute to improved energy efficiency and reduced operational costs for data center facilities.

In various embodiments, the server rack 302 may incorporate advanced cooling systems to manage the heat generated by the power distribution components and server components 310. These cooling systems may include liquid cooling solutions, precision air handling units, or advanced airflow management techniques to ensure optimal operating temperatures within the rack enclosure.

In various embodiments, the distribution controller 304 may integrate with broader data center infrastructure management (DCIM) systems. This integration may allow for coordinated management of power distribution across multiple server racks and facilities, enabling enterprise-wide power optimization strategies and centralized monitoring of distributed data center resources.

In various embodiments, the monitoring system 312 may incorporate artificial intelligence and machine learning algorithms to provide predictive maintenance capabilities. By analyzing historical data and identifying patterns in power consumption and system performance, the monitoring system 312 may be able to predict potential equipment failures or inefficiencies before they occur, enabling proactive maintenance and minimizing downtime.

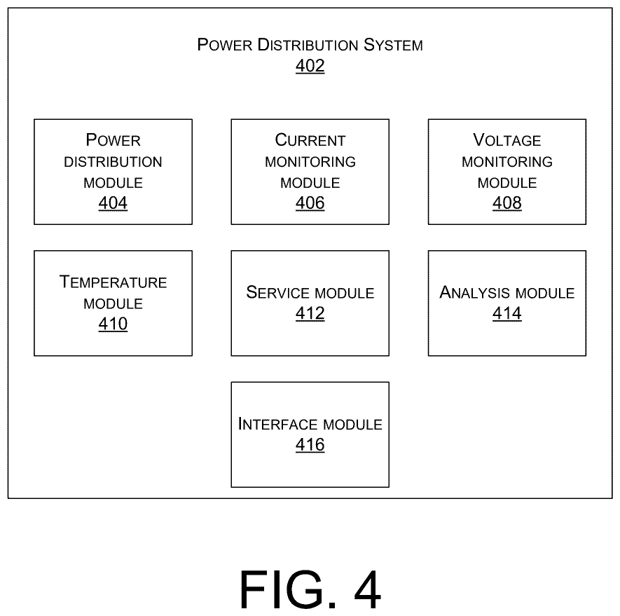

FIG. 4 illustrates a power distribution system 402, in accordance with one embodiment. As an option, the power distribution system 402 may be implemented in the context of any one or more of the embodiments set forth in any previous and/or subsequent Figures and/or description thereof. Of course, however, the power distribution system 402 may be implemented in the context of any desired environment. Further, the aforementioned definitions may equally apply to the description below.

The power distribution system 402 includes a power distribution module 404, a current monitoring module 406, a voltage monitoring module 408, a temperature module 410, a service module 412, an analysis module 414, and an interface module 416. These components work together to provide comprehensive power distribution, monitoring, and management capabilities for data center or telecommunications facility environments.

The power distribution module 404 serves as the central component for managing power distribution within the power distribution system 402. The power distribution module 404 may receive power from the power source 102 and distribute power to multiple output circuits 204. The power distribution module 404 may incorporate bus bars, wiring, and connectors to efficiently route power to various system components 108. In some cases, the power distribution module 404 may include integrated circuit breakers or fuses to provide overcurrent protection for individual output circuits 204. The power distribution module 404 may be designed to handle high current loads, with the capacity to provide up to 60 amps per circuit. The power distribution module 404 may incorporate advanced thermal management features to ensure efficient operation within confined spaces. These features may include passive heat sinks, active cooling systems, or thermally optimized component layouts.

A current monitoring module 406 tracks and measures the electrical current flowing through each output circuit 204 of the power distribution system 402. The current monitoring module 406 may utilize current transformers, Hall effect sensors, or other current sensing technologies to provide accurate real-time measurements. The current monitoring module 406 may be capable of measuring both AC and DC currents, depending on the specific requirements of the power distribution system 402. In some cases, the current monitoring module 406 may incorporate high-speed sampling capabilities to detect rapid changes in current draw. The current monitoring module 406 may include signal conditioning and analog-to-digital conversion circuitry to process the raw current measurements and provide digital data to the analysis module 414. This digital data may be used for real-time monitoring, trend analysis, and alert generation.

A voltage monitoring module 408 measures and tracks the voltage levels at various points within the power distribution system 402. The voltage monitoring module 408 may use precision voltage dividers, differential amplifiers, or dedicated voltage sensing ICs to accurately measure voltage levels. In some cases, the voltage monitoring module 408 may be capable of measuring both line-to-line and line-to-neutral voltages in three-phase power distribution systems. The voltage monitoring module 408 may incorporate high-impedance inputs to minimize the impact on the measured circuits. The voltage monitoring module 408 may include overvoltage and undervoltage detection capabilities, allowing for rapid identification of potentially harmful voltage fluctuations. This information may be used by the analysis module 414 to trigger protective actions or generate alerts.

A temperature module 410 monitors the thermal conditions within the power distribution system 402. The temperature module 410 may use thermistors, thermocouples, or integrated temperature sensors to measure temperatures at critical points throughout the system. The temperature module 410 may be designed to monitor both ambient temperatures within the server rack 104 and specific component temperatures, such as bus bar connections or power semiconductor devices. In some cases, the temperature module 410 may incorporate infrared sensors for non-contact temperature measurement of hard-to-reach components. The temperature module 410 may provide temperature data to the analysis module 414 for trend analysis and thermal management. This data may be used to optimize cooling strategies, predict potential overheating issues, and ensure the long-term reliability of the power distribution system 402.

A service module 412 facilitates maintenance and troubleshooting operations for the power distribution system 402. The service module 412 may provide diagnostic tools, system logs, and configuration management capabilities to assist technicians in maintaining and optimizing the system. In some cases, the service module 412 may incorporate remote access capabilities, allowing authorized personnel to perform diagnostics and configuration changes from off-site locations. The service module 412 may include secure authentication mechanisms to ensure that only authorized users can access sensitive system functions. The service module 412 may maintain a comprehensive event log, recording all significant system events, configuration changes, and maintenance activities. This log may be used for auditing purposes, troubleshooting historical issues, and identifying patterns that may indicate potential system problems.

An analysis module 414 processes and analyzes the data collected by the current monitoring module 406, voltage monitoring module 408, and temperature module 410. The analysis module 414 may use advanced algorithms and statistical techniques to identify trends, detect anomalies, and predict potential issues within the power distribution system 402. The analysis module 414 may incorporate machine learning capabilities to improve its analytical performance over time. By learning from historical data and system behavior, the analysis module 414 may become increasingly accurate in predicting potential failures or inefficiencies. In some cases, the analysis module 414 may perform complex power quality analysis, including harmonic analysis, power factor calculations, and energy consumption profiling. This advanced analysis may help identify opportunities for energy efficiency improvements and power quality optimization.

An interface module 416 provides a means for users or administrators to interact with the power distribution system 402. The interface module 416 may offer both local and remote access options, allowing for flexible system management and monitoring. The interface module 416 may include a graphical user interface that presents real-time data, historical trends, and system alerts in an easily understandable format. In some cases, the interface module 416 may support customizable dashboards, allowing users to focus on the most relevant information for their specific needs. The interface module 416 may incorporate advanced reporting capabilities, enabling users to generate detailed reports on power usage, efficiency metrics, and system performance over time. These reports may be customizable and exportable in various formats to support different analytical and reporting requirements.

The components of the power distribution system 402 work together to provide comprehensive power distribution, monitoring, and management capabilities. The power distribution module 404 serves as the central hub for power distribution, while the current monitoring module 406, voltage monitoring module 408, and temperature module 410 continuously collect data on system performance and conditions.

The service module 412 supports maintenance and troubleshooting activities, ensuring the long-term reliability and efficiency of the power distribution system 402. The analysis module 414 processes the collected data, identifying trends, detecting anomalies, and providing valuable insights into system performance and potential issues. The interface module 416 ties the system together from a user perspective, providing accessible and actionable information to system administrators and facility managers. Through the interface module 416, users can monitor real-time system status, analyze historical trends, and receive alerts about potential issues. The power distribution system 402 enables proactive management of power resources within data center or telecommunications environments. By providing real-time monitoring and analysis capabilities, the system allows for rapid response to changing power demands or potential problems.

The integration of multiple monitoring functions (current, voltage, and temperature) within a single system provides a comprehensive view of power distribution health and performance. This holistic approach to monitoring may enable more effective troubleshooting and optimization of power distribution strategies.

In various embodiments, the power distribution module 404 may incorporate solid-state switching devices, such as silicon-controlled rectifiers (SCRs) or insulated-gate bipolar transistors (IGBTs), in place of traditional electromechanical relays or circuit breakers. These solid-state devices may offer faster switching speeds, improved reliability, and the ability to implement advanced power control strategies.

In various embodiments, the analysis module 414 may integrate with external data sources, such as weather forecasts or energy pricing information, to optimize power distribution and usage strategies. For example, the system may adjust power allocation based on predicted renewable energy availability or implement load-shedding strategies during periods of high energy costs.

In various embodiments, the power distribution system 402 may incorporate energy storage capabilities, such as battery banks or supercapacitors. These energy storage systems may be managed by the power distribution module 404 and monitored by the current monitoring module 406, voltage monitoring module 408, and temperature module 410. The integration of energy storage may enable advanced power management strategies, such as peak shaving or providing uninterruptible power supply functionality.

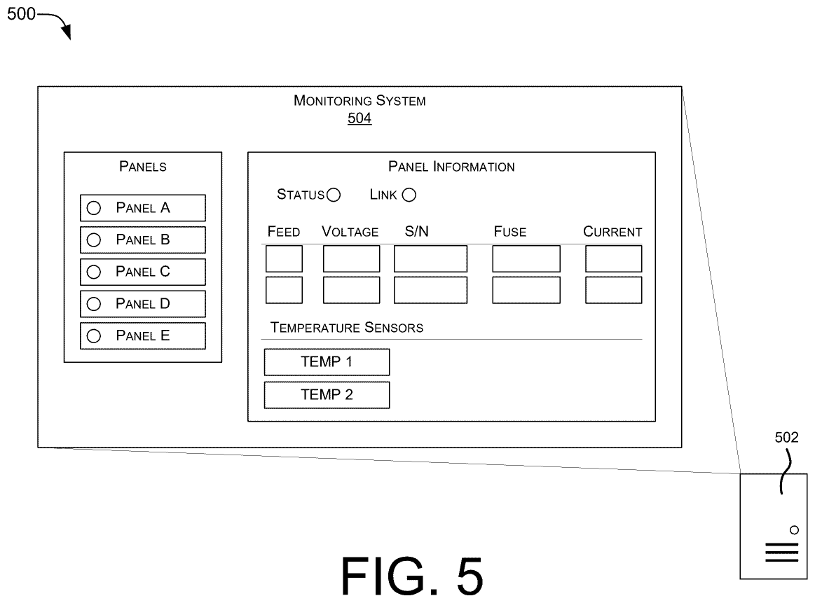

FIG. 5 illustrates a monitoring interface 500 for a power distribution system, in accordance with one embodiment. As an option, the monitoring interface 500 may be implemented in the context of any one or more of the embodiments set forth in any previous and/or subsequent Figures and/or description thereof. Of course, however, the monitoring interface 500 may be implemented in the context of any desired environment. Further, the aforementioned definitions may equally apply to the description below. The monitoring interface 500 includes a computing system 502 and a user interface 504. These components work together to provide comprehensive monitoring and control capabilities for the power distribution system.

A computing system 502 processes and manages data related to the power distribution system. The computing system 502 may include processors, memory, storage devices, and network interfaces to handle the complex tasks of data collection, analysis, and presentation. In some cases, the computing system 502 may be a dedicated server or a virtual machine running in a data center environment. The computing system 502 may be configured with specialized software for power management and monitoring tasks. This software may include modules for data acquisition, real-time analysis, historical trend tracking, and alert generation.

The computing system 502 may incorporate redundancy features to ensure continuous operation of the monitoring system. These features may include redundant power supplies, RAID storage configurations, and failover clustering capabilities. In some cases, the computing system 502 may be distributed across multiple physical or virtual machines to improve performance and reliability. The computing system 502 may also include advanced security features to protect sensitive power distribution data. These features may include encryption for data at rest and in transit, multi-factor authentication for system access, and comprehensive audit logging capabilities.

A user interface 504 provides a visual representation of the power distribution system's status and allows for user interaction. The user interface 504 may be a web-based application accessible through standard browsers or a dedicated software client installed on operator workstations. The user interface 504 may present real-time data, historical trends, and system alerts in an easily understandable format. The user interface 504 may include customizable dashboards that allow users to focus on the most relevant information for their specific needs. These dashboards may feature widgets for displaying key performance indicators, graphical representations of power flow, and status indicators for individual components of the power distribution system. The user interface 504 may also provide interactive controls for managing the power distribution system. These controls may allow authorized users to remotely cycle power to specific outputs, adjust alarm thresholds, or initiate diagnostic routines. The user interface 504 may incorporate role-based access control to ensure that users only have access to functions appropriate for their responsibilities.

The components of the monitoring interface 500 work together to provide comprehensive monitoring and control capabilities for the power distribution system. The computing system 502 collects and processes data from various sensors and components within the power distribution system. This data may include current and voltage measurements, temperature readings, and status information from field effect transistors and overcurrent devices. Though examples may be described herein with reference to a field effect transistor for a switch device, the switch device may also include components such as relays, bipolar junction transistors (BJTs), insulated gate bipolar transistors (IGBTs), solid state relays (SSRs), or other such switching devices. The computing system 502 analyzes the collected data in real-time to detect anomalies, track trends, and generate alerts when predefined thresholds are exceeded. The analysis may include complex calculations such as power factor analysis, harmonic distortion measurements, and predictive maintenance algorithms. The results of this analysis are then presented to users through the user interface 504. The user interface 504 provides a visual representation of the power distribution system's status, allowing operators to quickly assess the health and performance of the system. Real-time updates ensure that users always have access to the most current information.

The user interface 504 also serves as a control point for the power distribution system. Through the interface, authorized users can interact with the system, making adjustments and initiating actions as needed. For example, an operator may use the interface to remotely cycle power to a specific server component that has become unresponsive.

The monitoring interface 500 enables proactive management of the power distribution system by providing early warning of potential issues. By analyzing trends and patterns in the collected data, the system may identify equipment that is showing signs of degradation before a failure occurs. This predictive capability allows for scheduled maintenance and replacement of components, reducing the risk of unexpected downtime.

In various embodiments, the computing system 502 may incorporate machine learning algorithms to improve its analytical capabilities over time. These algorithms may learn from historical data and system behavior to refine predictive models and anomaly detection thresholds. This adaptive approach may lead to more accurate predictions of potential issues and more efficient power management strategies.

In various embodiments, the user interface 504 may be extended to mobile devices, allowing operators to monitor and control the power distribution system from smartphones or tablets. This mobile capability may include push notifications for critical alerts, enabling rapid response to urgent situations even when operators are away from their workstations.

In various embodiments, the monitoring interface 500 may integrate with broader data center infrastructure management (DCIM) systems. This integration may allow for coordinated management of power distribution across multiple server racks and facilities, enabling enterprise-wide power optimization strategies and centralized monitoring of distributed data center resources.

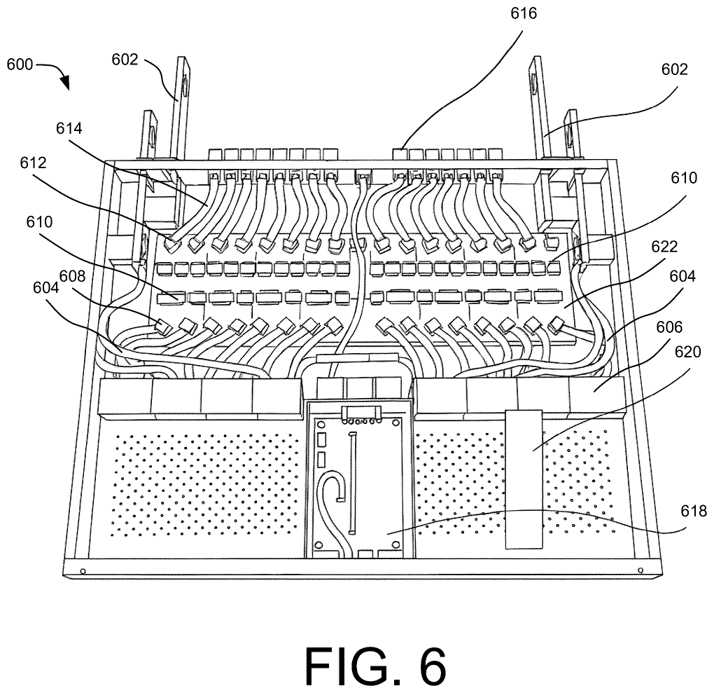

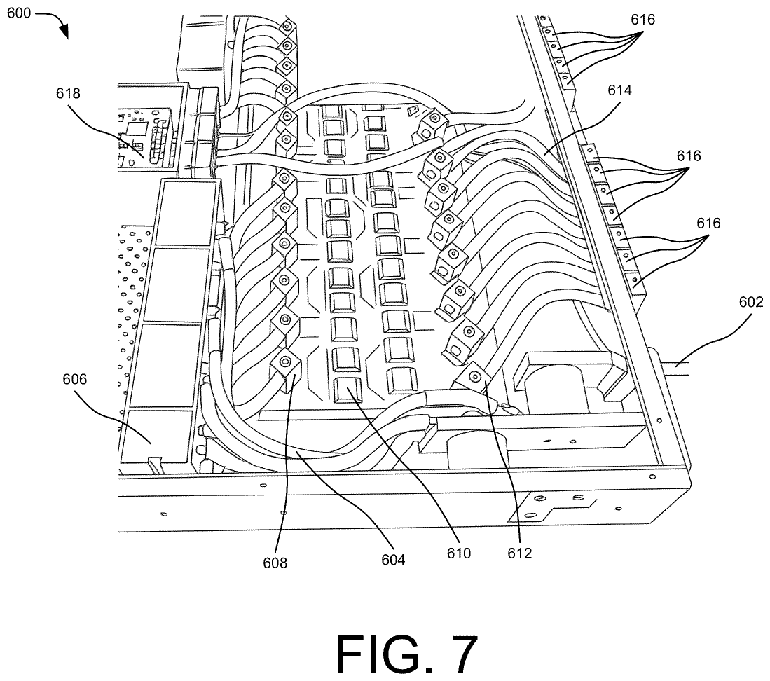

FIG. 6 and FIG. 7 illustrate internal components of a power distribution unit 600, in accordance with one embodiment. As an option, the power distribution unit 600 may be implemented in the context of any one or more of the embodiments set forth in any previous and/or subsequent Figures and/or description thereof. Of course, however, the power distribution unit 600 may be implemented in the context of any desired environment. Further, the aforementioned definitions may equally apply to the description below.

The power distribution unit 600 includes a bus bar 602, connections 604, 608, 612, and 614, a switch 606, a field effect transistor 610, power outputs 616, a controller 618, an overcurrent protection device 620, and a circuit board 622.

The bus bar 602 serves as the main power distribution pathway within the power distribution unit 600. The bus bar 602 may be constructed from a highly conductive material such as copper or aluminum to minimize power losses. In some cases, the bus bar 602 may be designed with a cross-sectional area optimized for the expected current load of the power distribution unit 600. The bus bar 602 may incorporate cooling features such as heat sinks or forced air cooling to manage thermal loads during high-current operation. Connections 604, 608, 612, and 614 provide electrical pathways between various components of the power distribution unit 600. These connections may be implemented using high-quality wiring or printed circuit board traces designed to handle the expected current loads. In some cases, the connections may incorporate shielding or isolation techniques to minimize electromagnetic interference between different circuits within the power distribution unit 600. The connections may be designed with redundancy features to ensure continued operation in case of a single connection failure.

A switch 606 allows for manual or automated control of power flow within the power distribution unit 600. The switch 606 may include electromechanical switches such as relays or may also include semiconductor switches and may include a solid-state device such as a MOSFET or IGBT or other switching devices such as relays, bipolar junction transistors (BJTs), solid state relays (SSRs), or other such switching devices for fast switching capabilities and improved reliability compared to mechanical switches. In some cases, the switch 606 may incorporate advanced features such as soft-start functionality to minimize inrush currents when activating circuits. The switch 606 may be controlled by the controller 618 to enable remote operation and integration with power management systems.

A field effect transistor 610 provides precise control over power delivery to individual circuits within the power distribution unit 600. Though examples may be described herein with reference to a field effect transistor for a switch device, the switch device may also include components such as relays, bipolar junction transistors (BJTs), insulated gate bipolar transistors (IGBTs), solid state relays (SSRs), or other such switching devices. The field effect transistor 610 may be selected for its low on-state resistance and high current handling capabilities to minimize power losses. In some cases, the field effect transistor 610 may incorporate built-in current sensing capabilities to provide real-time feedback on power consumption. The field effect transistor 610 may be controlled by the controller 618 to enable features such as programmable current limiting and overcurrent protection.

Power outputs 616 serve as the connection points for delivering power to external devices or system components. The power outputs 616 may be designed to accommodate various connector types commonly used in data center and telecommunications equipment. In some cases, the power outputs 616 may incorporate individual power metering capabilities to provide granular monitoring of power consumption. The power outputs 616 may be individually controllable by the controller 618, allowing for selective power cycling of connected devices.

A controller 618 manages the overall operation of the power distribution unit 600. The controller 618 may be a microprocessor-based system with firmware designed for power management and monitoring tasks. In some cases, the controller 618 may incorporate machine learning algorithms to optimize power distribution based on historical usage patterns and real-time data. The controller 618 may communicate with external management systems using standard protocols such as SNMP or Modbus, enabling integration with existing data center management platforms.

An overcurrent protection device 620 provides safeguards against excessive current flow that could damage connected equipment or the power distribution unit 600 itself. The overcurrent protection device 620 may be implemented as a circuit breaker or fuse, selected based on the specific current ratings required for each output circuit. In some cases, the overcurrent protection device 620 may incorporate electronic trip units that provide advanced protection features such as adjustable trip settings and time-delay functions. The overcurrent protection device 620 may be monitored by the controller 618 to provide real-time status information and enable remote reset capabilities.

A circuit board 622 provides the physical substrate for mounting and interconnecting various electronic components within the power distribution unit 600. The circuit board 622 may be a multi-layer design to accommodate complex routing requirements and provide proper isolation between different circuit sections. In some cases, the circuit board 622 may incorporate advanced materials such as high-temperature laminates to improve thermal management. The circuit board 622 may include test points and diagnostic interfaces to facilitate maintenance and troubleshooting of the power distribution unit 600.

The components of the power distribution unit 600 provide controlled and protected power distribution. The bus bar 602 receives power from the power source and distributes power to multiple output circuits through the connections 604, 608, 612, and 614. Each output circuit includes the switch 606, field effect transistor 610, and overcurrent protection device 620 connected in series. This arrangement allows for multiple layers of control and protection for the power outputs 616.

The controller 618 serves as the central management unit for the power distribution unit 600. The controller 618 monitors the status of all components and manages the operation of the switches 606 and field effect transistors 610. This enables features such as remote power cycling, scheduled power sequences, and intelligent load balancing across multiple output circuits. The power distribution unit 600 enables granular control and monitoring of power distribution. The controller 618 may selectively enable or disable power to specific power outputs 616 by controlling the corresponding switches 606 and field effect transistors 610. This capability may be useful for scheduled maintenance, energy saving during off-peak hours, or rapid response to fault conditions. The combination of field effect transistors 610 and overcurrent protection devices 620 provides multiple layers of protection for connected system components. The overcurrent protection devices 620 offer traditional circuit protection, while the field effect transistors 610 allow for rapid power cut-off in response to software-detected anomalies or user commands. This multi-layered approach enhances the overall reliability and safety of the power distribution system.

The power distribution unit 600 incorporates advanced monitoring capabilities through the controller 618 and various sensing elements integrated into the components. This allows for real-time tracking of current, voltage, and temperature across all output circuits. The collected data may be used for trend analysis, predictive maintenance, and optimization of power distribution strategies.

In various embodiments, the power distribution unit 600 may incorporate energy storage capabilities such as integrated battery banks or supercapacitors. These energy storage systems may be managed by the controller 618 to provide uninterruptible power supply functionality or enable advanced power management strategies such as peak shaving during high-demand periods.

In various embodiments, the field effect transistors 610 may be replaced or supplemented with other solid-state switching devices such as insulated-gate bipolar transistors (IGBTs) or silicon-controlled rectifiers (SCRs). These alternative devices may offer different performance characteristics suitable for specific applications or power levels, potentially improving efficiency or enabling new control strategies.

In various embodiments, the power distribution unit 600 may incorporate advanced thermal management systems such as liquid cooling or phase-change materials. These thermal management solutions may allow for higher power density within the same form factor, enabling the power distribution unit 600 to handle increased power loads without compromising reliability or efficiency.

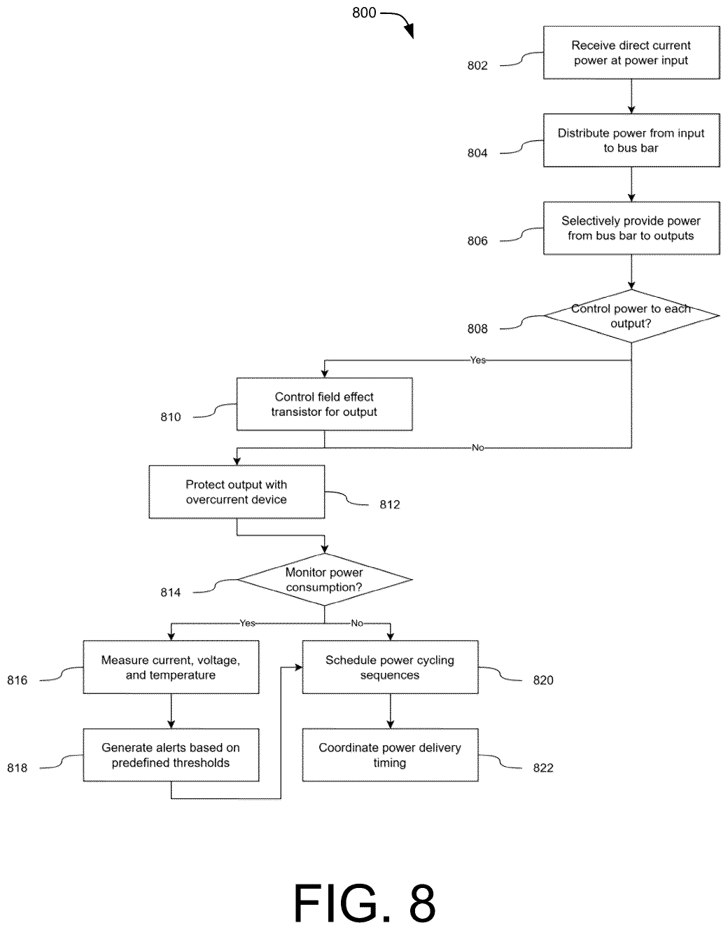

FIG. 8 illustrates a method 800 for controlling power distribution in a direct-current distribution system, in accordance with one embodiment. As an option, the method 800 may be implemented in the context of any one or more of the embodiments set forth in any previous and/or subsequent Figures and/or description thereof. Of course, however, the method 800 may be implemented in the context of any desired environment. Further, the aforementioned definitions may equally apply to the description below.

The method 800 includes a series of steps and decision points for managing power distribution within a direct-current system. The method 800 begins with step 802 of receiving direct-current power at a power input. In this step, the power distribution system may receive power from the power source, which may be a high-capacity direct-current power supply designed for data center or telecommunications applications.

Step 802 may involve several sub-processes to ensure the safe and efficient reception of power. For example, the power input may incorporate surge protection devices to safeguard against voltage spikes or transients that could damage downstream components. Additionally, the power input may include filtering circuits to remove any noise or harmonics present in the incoming power, ensuring a clean power supply for the distribution system. In some cases, step 802 may also involve monitoring the incoming power characteristics, such as voltage level and current draw. This monitoring may be performed by the current monitoring module and voltage monitoring module, providing real-time data on the power being received by the system.

Following the reception of power, the method 800 proceeds to step 804 of distributing power from the input to a bus bar. This step may involve routing the received power through the power distribution module to the bus bar, which serves as the main power distribution pathway within the power distribution panel. Step 804 may include several technical considerations to ensure efficient power distribution. For example, the bus bar may be designed with a specific cross-sectional area and material composition to minimize power losses due to resistance. The connection between the power input and the bus bar may be engineered to handle high current loads, potentially incorporating multiple parallel conductors or specialized high-current connectors. In some implementations, step 804 may also involve activating any necessary switching or protection devices between the power input and the bus bar. This could include closing main circuit breakers or activating solid-state switches to establish the power flow to the bus bar.

The method 800 then moves to step 806 of selectively providing power from the bus bar to outputs. This step may involve controlling the field effect transistors or other such switch devices as described herein associated with each output circuit to manage power delivery to the system components. Step 806 may be a complex process involving multiple sub-steps and decision-making algorithms. For example, the distribution controller may assess the current power demands of connected system components and prioritize power delivery based on predefined criteria. This could involve sequentially activating outputs to avoid large inrush currents that might occur if all outputs were energized simultaneously. Additionally, step 806 may incorporate load balancing techniques to distribute power evenly across available outputs, potentially improving overall system efficiency and reducing stress on individual components.

After initiating power distribution, the method 800 reaches a decision point 808 to determine whether to control power to each output. This decision point may involve evaluating various factors such as current system load, scheduled maintenance activities, or specific requests from the control interface. If the decision is made to control power to the outputs, the method 800 proceeds to step 810 of controlling a field effect transistor (or other switch device) for the output. This step may involve sending control signals from the controller to the gate of the field effect transistor, modulating its conductivity to adjust power flow.

Step 810 may incorporate sophisticated control algorithms to manage power delivery. For example, the controller may implement pulse-width modulation techniques to precisely control the amount of power delivered to each output. This could allow for fine-grained power management, potentially enabling features such as soft-start capabilities or dynamic power allocation based on real-time demand. In some implementations, step 810 may also involve monitoring the performance of the field effect transistor itself. This could include measuring parameters such as on-state resistance or switching times to ensure optimal operation and detect any potential degradation over time.

Following the control of the field effect transistor, the method 800 moves to step 812 of protecting the output with an overcurrent device. This step may involve configuring and monitoring the overcurrent protection device associated with each output circuit. Step 812 may encompass a range of protection strategies depending on the specific requirements of the system. For example, the overcurrent device may be a fast-acting fuse for applications requiring rapid fault isolation, or it could be an electronic circuit breaker with adjustable trip characteristics for more flexible protection schemes. In some cases, step 812 may also involve coordination between the overcurrent device and the field effect transistor controlled in step 810. This coordination could enable advanced protection features, such as using the field effect transistor for fast current limiting before the overcurrent device trips, potentially avoiding nuisance trips while still providing robust protection.

The method 800 then reaches another decision point 814 to determine whether to monitor power consumption. This decision may be based on factors such as system configuration settings, user preferences specified through the control interface, or specific monitoring requirements for certain critical components. If monitoring is to be performed, the method 800 proceeds to step 816 of measuring current, voltage, and temperature. This step may involve utilizing the current monitoring module, voltage monitoring module, and temperature module to collect comprehensive data on the power distribution system's performance.

Step 816 may employ a variety of sensing technologies to gather accurate measurements. For current monitoring, the system may use precision current transformers or Hall effect sensors. Voltage measurements may be obtained through high-impedance voltage dividers or dedicated voltage sensing ICs. Temperature monitoring may involve strategically placed thermistors or integrated temperature sensors on key components. In some implementations, step 816 may also involve synchronizing measurements across multiple outputs to provide a holistic view of the system's power distribution at any given moment. This synchronized data collection could enable advanced analysis of power flow and thermal patterns within the system.

Following the measurement process, the method 800 moves to step 818 of generating alerts based on predefined thresholds. This step may involve comparing the measured values from step 816 against a set of predefined limits or thresholds stored in the controller or analysis module. Step 818 may incorporate multi-tiered alerting systems to provide graduated responses to different levels of concern. For example, minor deviations from expected values might trigger low-priority notifications, while more significant anomalies could generate urgent alerts requiring immediate attention. In some cases, step 818 may also involve predictive alerting based on trend analysis. By analyzing historical data and current measurements, the system may be able to forecast potential issues before they reach critical thresholds, enabling proactive maintenance and reducing the risk of unexpected downtime.

If power monitoring is not selected at the decision point 814, or following the alert generation in step 818, the method 800 proceeds to step 820 of scheduling power cycling sequences. This step may involve creating and managing schedules for systematically powering on and off various outputs or groups of outputs. Step 820 may incorporate complex scheduling algorithms to optimize power cycling based on various factors. For example, the system may consider historical usage patterns, current power availability, and predefined priority levels for different system components when creating power cycling schedules. In some implementations, step 820 may also involve adaptive scheduling that adjusts based on real-time conditions. For instance, if certain high-priority components unexpectedly require more power, the scheduling system may dynamically adjust the power cycling sequence to ensure critical operations are not interrupted.

Finally, the method 800 concludes with step 822 of coordinating power delivery timing. This step may involve managing the precise timing of power activation and deactivation across multiple outputs to optimize system performance and stability. Step 822 may employ sophisticated timing control mechanisms to ensure smooth power transitions. For example, the system may implement staggered power-up sequences to avoid large inrush currents that could stress power supplies or trigger protective devices. Similarly, power-down sequences may be carefully timed to ensure orderly shutdown of interconnected systems. In some cases, step 822 may also involve coordination with external systems or equipment. For instance, the power distribution system may synchronize its power delivery timing with the startup sequences of connected servers or networking equipment to ensure proper initialization and avoid potential conflicts.

The steps and decision points of the method 800 provide comprehensive control and monitoring of power distribution within a direct-current system. The initial steps of receiving power (step 802) and distributing it to the bus bar (step 804) establish the foundation for power availability within the system. The selective provision of power to outputs (step 806) then allows for granular control over which components receive power and when. The decision point for controlling power to each output (decision point 808) and the subsequent steps of controlling the field effect transistor (step 810) and protecting the output with an overcurrent device (step 812) work in concert to provide both precise power control and robust protection for each output circuit. This combination allows for dynamic power management while maintaining safety and reliability.

The monitoring-related steps, including the decision to monitor power consumption (decision point 814), measuring current, voltage, and temperature (step 816), and generating alerts (step 818), form a comprehensive system for tracking power distribution performance. These steps enable real-time visibility into the system's operation, facilitating quick identification and response to potential issues. The final steps of scheduling power cycling sequences (step 820) and coordinating power delivery timing (step 822) add an additional layer of control and optimization to the power distribution process. These steps allow for systematic management of power delivery over time, potentially improving energy efficiency and system reliability. Together, these steps and decision points create a closed-loop system for power distribution management. The method 800 continuously cycles through processes of power delivery, monitoring, and adjustment, allowing for responsive and efficient operation of the power distribution system.

The interaction between the control steps (such as controlling the field effect transistor in step 810) and the monitoring steps (such as measuring parameters in step 816) creates a feedback loop that enables adaptive power management. For example, if the monitoring process detects a trend of increasing power consumption on a particular output, the control system can adjust the field effect transistor settings to optimize power delivery or trigger alerts if consumption approaches predefined limits. Furthermore, the coordination between power cycling schedules (step 820) and real-time power control (steps 806, 810) allows for flexible power management strategies. The system can implement long-term power management plans through scheduling while still maintaining the ability to respond quickly to immediate power needs or unexpected events.

In various embodiments, the method 800 may incorporate machine learning algorithms to optimize its decision-making processes. For example, the system may analyze historical power consumption patterns and environmental data to predict future power needs more accurately. This predictive capability could enhance the scheduling of power cycling sequences (step 820) and improve the efficiency of power distribution.

In various embodiments, the method 800 may be extended to include power quality analysis as part of the monitoring process. In addition to measuring basic parameters like current and voltage (step 816), the system may perform more advanced analyses such as harmonic distortion measurement or power factor calculation. This enhanced monitoring could provide deeper insights into the health and efficiency of the power distribution system and connected equipment.

In various embodiments, the method 800 may be integrated with broader data center management systems. For example, the power distribution control and monitoring processes could be coordinated with server workload management, cooling system operation, and facility-wide energy management strategies. This integration could enable more holistic optimization of data center operations, potentially leading to improved energy efficiency and reduced operational costs.

A number of implementations have been described. Nevertheless, it will be understood that various modifications may be made without departing from the spirit and scope of the disclosure. Accordingly, other implementations are within the scope of the following claims.

1. A power distribution panel for distributing direct-current power to a plurality of components, comprising:
a power input configured to receive direct-current power from a source;
a bus bar electrically coupled to the power input; and
a plurality of outputs electrically coupled to the bus bar, each of the plurality of outputs coupled to the bus bar through a respective:
switching device; and
overcurrent device coupled in series with the switching device, wherein the switching device is controllable by a controller of the power distribution panel.

2. The power distribution panel of claim 1, wherein the controller is configured to remotely control power delivery to each of the plurality of outputs by controlling respective switching devices.

3. The power distribution panel of claim 2, wherein the controller is further configured to schedule power cycling sequences for the plurality of outputs.

4. The power distribution panel of claim 1, wherein the overcurrent device comprises at least one of a circuit breaker or a fuse and the switch device comprises at least one of a field effect transistor, relay, bipolar junction transistor, insulated gate bipolar transistor, or solid state relay.

5. The power distribution panel of claim 1, further comprising a monitoring system configured to monitor power consumption of each of the plurality of outputs.

6. The power distribution panel of claim 5, wherein the monitoring system is configured to provide real-time data on current, voltage, and temperature for each of the plurality of outputs.

7. The power distribution panel of claim 6, wherein the monitoring system is further configured to generate alerts based on predefined threshold values for current, voltage, and temperature.

8. A system for distributing direct-current power, comprising:
a server rack; and
a power distribution panel mounted in the server rack, the power distribution panel comprising:
a power input for receiving direct-current power;
a bus bar coupled to the power input; and
a plurality of output circuits, each output circuit comprising:
a switch device coupled to the bus bar;
an overcurrent protection device coupled in series with the switch device; and
an output connection for providing power to a component in the server rack.

9. The system of claim 8, further comprising a controller configured to remotely control power delivery to each of the plurality of output circuits by controlling respective switch devices.

10. The system of claim 9, wherein the controller is further configured to schedule power cycling sequences for the plurality of output circuits.

11. The system of claim 10, wherein scheduling power cycling sequences comprises coordinating power delivery timing to avoid simultaneous activation of multiple output circuits.

12. The system of claim 8, further comprising a monitoring system configured to monitor power consumption of each of the plurality of output circuits and provide real-time data on current, voltage, and temperature.

13. The system of claim 12, wherein the monitoring system is further configured to generate alerts based on predefined threshold values for current, voltage, and temperature.

14. A method of distributing power using a power distribution panel, comprising:
receiving direct-current power at a power input of the power distribution panel;
distributing the direct-current power from the power input to a bus bar; and
selectively providing power from the bus bar to a plurality of outputs, wherein providing power to the plurality of outputs comprises:
controlling a switch device coupled between the bus bar and an output of the plurality of outputs; and
protecting the output with an overcurrent device coupled in series with the switch device.

15. The method of claim 14, further comprising monitoring power consumption of each of the plurality of outputs.

16. The method of claim 15, wherein monitoring power consumption comprises measuring current, voltage, and temperature for each of the plurality of outputs.

17. The method of claim 16, further comprising generating alerts based on predefined threshold values for current, voltage, and temperature.

18. The method of claim 14, further comprising remotely controlling power delivery to each of the plurality of outputs by controlling respective switch devices.

19. The method of claim 18, further comprising scheduling power cycling sequences for the plurality of outputs.

20. The method of claim 19, wherein scheduling power cycling sequences comprises coordinating power delivery timing to avoid simultaneous activation of multiple outputs.
